(19) United States
(12) Patent Application Publication
(10) Pub. No.: US 2013/0077281 A1
(43) Pub. Date: Mar. 28, 2013

(54) CHIP ELEMENTS MOUNTED ON WIRES HAVING AN INCIPIENT BREAKING POINT

(71) Applicants: Jean Brun, Champagnier (FR); Francois Frassati, Voreppe (FR); Dominique Vicard, Bernin (FR)

(72) Inventors: Jean Brun, Champagnier (FR); Francois Frassati, Voreppe (FR); Dominique Vicard, Bernin (FR)

(73) Assignee: Commissariat A L'Energie Atomique Et Aux Energies Alternatives, Paris (FR)

(21) Appl. No.: 13/703,272

(22) PCT Filed: Jun. 23, 2011
(86) PCT No.: PCT/FR2011/000360

§ 371 Date: Dec. 10, 2012

(30) Foreign Application Priority Data
Jun. 24, 2010 (FR) 10 02655

(51) Int. Cl. H05K 7/02; H05K 13/00

(52) U.S. Cl. CPC H05K 7/02; H05K 13/00
USPC 361/807; 29/592.1

(57) ABSTRACT

The invention relates to a chain including multiple microelectronic chip elements that are connected to a wire. The wire has notches that define preferred breaking points when the wire is subject to tensile stress. If the wire is conductive, the notches can be spread so that the length of the wire between a chip element and a notch is equal to the length of an antenna.

### BACKGROUND OF THE INVENTION

The invention relates to microelectronic chip elements, having a largest dimension that may be smaller than one millimeter, which are connected to wires, especially to form chains which can be more easily handled by automated systems.

### STATE OF THE ART

FIGS. 1A and 1B show a chain of microelectronic chip elements such as formed by a method described in patent application EP2099060.

FIG. 1A shows a section of the chain in top view. Several chip elements 10 of generally parallelepipedal shape are connected between two parallel wires 12a and 12b.

is FIG. 1B shows one of chip elements 10 in side view. The element is provided with two lateral grooves wherein wires 12a and 12b are installed therein. Such grooves may be provided with electric connection pads in the case where the wires are conductors and are used to transmit electric signals.

Wires 12a and 12b are most often used both to transmit electric signals and to connect together the chip elements, of small size, to form an assembly which can be more easily handled by automated systems.

Patent application WO2009004243 describes a use of a chain of the type in FIG. 1A to form radio frequency transceiver devices, especially used for identification purposes (RFID). Each chip element 10 then incoporates all RFID functions. Wires 12a and 12b are cut around each chip element to form a dipole antenna. This dipole antenna is formed of a strand of wire 12a on one side of the chip element and of a strand of wire 12b on the opposite side of the element.

FIG. 2 shows an object 4 having several RFC elements 16 thus formed incorporated therein.

Object 14 may be a tube which is desired to be marked at regular intervals with RFID elements. The tubes, continuously manufactured, are intended to be cut at lengths adapted to various needs. In this case, it is desired for each cut length to comprise at least one RFID element enabling to identify the tube. RFID elements regularly distributed in longer tube sections may be used to mark specific locations along the tube or to identify tube sections.

More generally, it may be considered useful to regularly incorporate RFID elements in a continuously manufactured object. Apart from tubes, ropes, profiles, fabrics, films, strips . . . can be mentioned.

The incorporation of a chain in a continuously manufactured object, for example, a tube being extruded, poses no specific problem since it is desired for the chip elements to remain connected in the form of a chain in the final object.

A problem is however posed if the chip elements of the chain are desired to be detached to be incorporated into the object, especially in the case where these chip elements would be RFID elements. In an automated tube extrusion process, for example, it cannot be envisaged to detach the chip elements and bring them one by one at the extrusion port level.

The antennas of the detached RFID chip elements cause handling problems. Indeed, the antennas should remain rectilinear, and it must thus be ascertained not to twist them.

### OBJECTS OF THE INVENTION

Means enabling to automate the incorporation of detached chip elements, especially RFID elements, in a continuously manufactured object, are thus desired.

To tend to fulfill this need, a chain comprising several microelectronic chip elements connected to a wire is provided. The wire has notches defining preferential breaking points when the wire is submitted to tensile stress. If the wire is a conductor, the notches may be spread so that the wire length comprised between a chip element and a notch is equal to the length of an antenna.

It is also provided a method for incorporating microelectronic chip elements in an object, comprising the following steps of: introducing into the object a chain comprising several microelectronic chip elements connected to a wire having notches defining preferential breaking points when the wire is submitted to tensile stress; and causing tensile stress in the object in the axis of the chain to break the wire at the notch level.

According to a development, the method comprises the following steps of: continuously forming the object from a stock of material; and introducing the chain of chip elements into the object being formed.

### BRIEF DESCRIPTION OF THE DRAWINGS

Other advantages and features will become more clearly apparent from the following description of particular embodiments of the invention given for non-restrictive example purposes only and represented in the appended drawings, in which:

FIGS. 1A and 1B, previously described, illustrate chip elements conditioned in the form of a chain;

FIG. 2, previously described, illustrates an elongated object incorporating chip elements performing RFID functions;

FIG. 3 illustrates an embodiment of a chip element chain enabling to automate the incorporation of the elements into a continuously manufactured object, especially in the case where these elements integrate RFID functions;

FIG. 4 illustrates a method for incorporating chip elements into an object being extruded;

FIG. 5 shows an embodiment of a chip element enabling to notch a wire; and

FIG. 6 shows an alternative embodiment of the chain of FIG. 3.

### DESCRIPTION OF A PREFERRED EMBODIMENT OF THE INVENTION

FIG. 3 shows an embodiment of a chip element chain enabling to detach the elements by simple tensile stress.

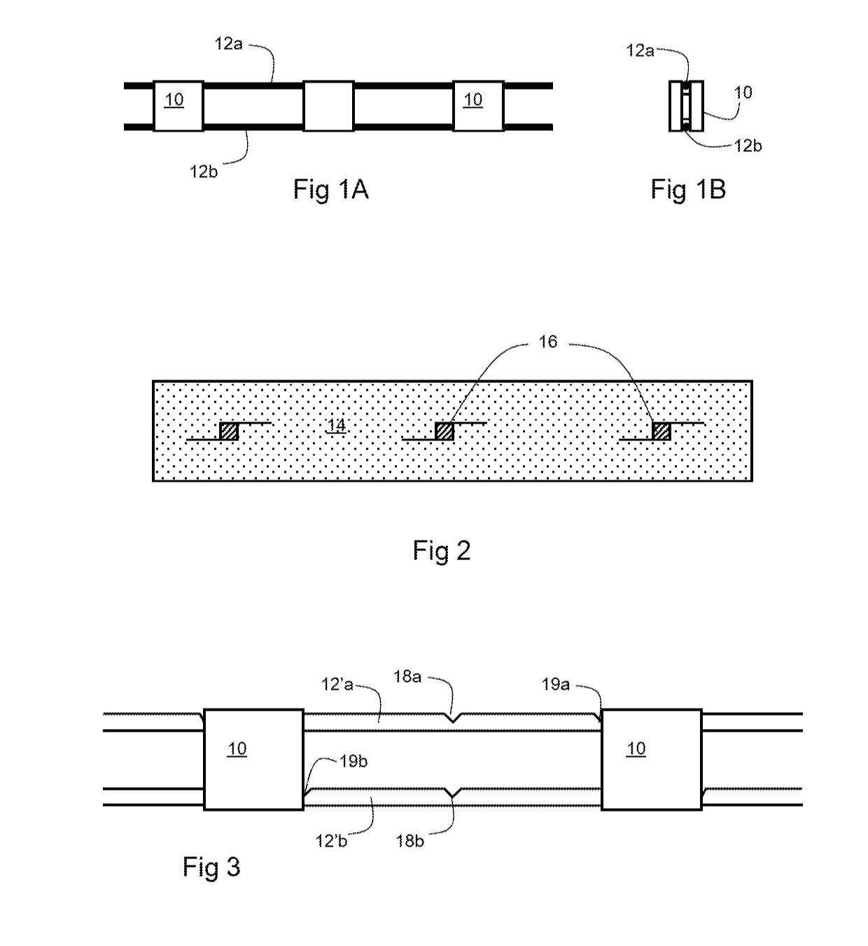

It shows, as an example, a chain of same configuration as that of FIG. 1A, where chip elements 10 are connected to two wires 12′a and 12′b by opposite sides.

The sections of wires 12′a and 12′b between two elements 10 each have a notch, respectively 18a and 18b. These notches define preferential breaking points, or intentional incipient breaking points, intended to break before any other point of the wires when a sufficient tensile stress is applied to the chain or the wires. It is thus intended to detach the chip elements of the chain by exerting a tensile stress on the chain, which causes the controlled breaking of the wires at the notch level.

The notches may be made in different ways, for example, by a saw cut, the driving in of a blade, a partial corrosion, or a partial melting. The first two examples (saw and blade) correspond to a cutting of the wire and the two other examples (corrosion and melting) correspond to a partial transformation of the wire. In other words, at least one of the notches is a cut or a partial transformation of wire 12a.

Notches 18a and 18b have been shown at the center of the wire sections between two chip elements 10. This is convenient in a situation where the wires have no function afterwards.

If the wires are to be used as a dipole antenna for an RFD element, notches 19a and 19b are rather provided on the opposite sides of wire sections 12a and 12b. Thus, when a tensile stress is exerted on the chain, elements 10 detach with antenna sections pointing in opposite directions, as shown for elements 16 of FIG. 2. This implies that the pitch between elements 10 in the chain corresponds to the antenna length.

In a more general case, if the chain pitch is greater than the antenna length, the four notches 18a to 19b are provided. Notches 18 then define the antenna length, and notches 19 are used to isolate a redundant wire section.

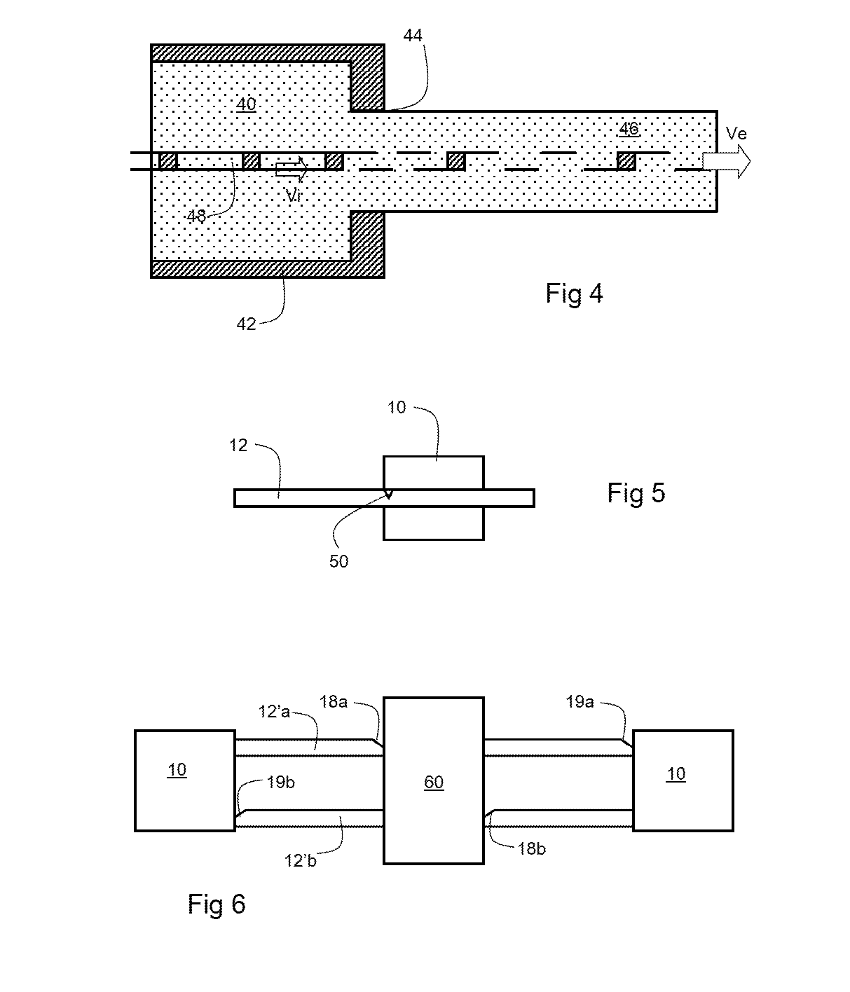

FIG. 4 illustrates a use of the notched wire chain of FIG. 3 in a method of extrusion of a profile or of a tube made of plastic material. An extrusion device, very schematically shown, comprises a material stock 40 in pasty form contained in a pressure feed tank 42. This tank is provided with a nozzle 44 through which profile or tube 46 is extruded at a constant speed indicated by an arrow Ve.

A chain 48 of chip elements of the type in FIG. 3 is inserted into the paste undergoing the extrusion at the level of nozzle 44 at a speed Vi smaller than extrusion speed Ve. Chain 48 is inserted into the paste in an area where the paste is sufficiently fluid to coat it. When the paste reaches the nozzle, it starts solidifying and imprisoning chain 48. The paste is then stretched and accelerated to reach speed Ve while pulling along chain 48. The chain being supplied at a speed smaller than Ve, it is submitted, in the acceleration area at the nozzle outlet, to a tensile stress which breaks the wires at the level of their notches, as shown. The pitch between chip elements which is found in the final profile is proportional to the chain pitch and to ratio Ve/Vi.

The chain type which has been shown in FIG. 4 comprises two notches (18, 19) in each wire section between two chip elements. Thus, at the same time as two wire sections of desired length connected to the elements, for example, used a dipole antenna, are created, isolated redundant sections are created.

For the clarity of the discussion, chain 48 has been shown in FIG. 4 in the axis of the extruded object 46. In a real extrusion installation, chain 48 will probably not be placed in material stock 40, where it will be difficult to handle. It Will rather be provided to introduce the chain through a lateral opening of the nozzle, as known in conventional extrusion installations, to incorporate linear elements into the extruded object.

It may also be envisaged to introduce the chain step by step into the object. At each step, a new chip element is presented in contact with the object so that the object draws it along by pulling on the wires, which break at the level of their notches. This method is more specifically adapted to the case of an object continuously formed by weaving, where a wire being woven imprisons the chip element so that it is drawn along by the woven object.

It may further be envisaged to incorporate a chain in an object without initially breaking the wires. Once the object has been produced, it is stretched along the axis of the chain causing a breaking of the wires at the level of their notches. This solution is rather adapted to stretching methods where the objects undergo a permanent deformation.

FIG. 5 shows in side view an embodiment of a chip element 10 enabling to notch wire 12 on forming of the chain. Element 10 comprises a groove having wire 12 (12a or 12b) inserted therein. One of the sidewalls of the groove comprises, at an end of the groove, a sharp rib 50 extending across part of the groove width. This rib notches wire 12 at the time when said wire is connected to the chip element. By providing the two grooves of each chip is element with such a rib, notches 19a and 19b of FIG. 3 may be formed with no additional step. If, further, the chain pitch corresponds to the desired antenna length, central notches 18a and 18b are superfluous and no additional notch forming step is necessary.

FIG. 4 also illustrates that the wire sections between two chip elements break in two locations, respectively corresponding to notches 18 and 19. In reality, if the wire is free to axially slide, the section will only break at the level of a single one of the two notches. The first notch to break releases the tensile stress on the wire section and protects the second notch. This behavior will change according to the adherence between the wire and the coating material. If the adherence is high, a result closer to that illustrated will be obtained.

FIG. 6 shows an alternative chip element chain enabling, if desired, to multiply the number of wire breaking points between two chip elements, whatever the nature of the material coating the chain.

An anchoring element 60 is connected to the sections of wire 12 between two chip elements 10 have. This anchoring element may be made in the same way as elements 10, except that it will comprise no microelectronic chip. Notches 18a and 18b, which were central in FIG. 3, are here displaced on either side of anchoring element 60, on wire sections opposite to those comprising notches 19.

As in FIG. 3, notches 18 define the length of the antenna sections which will remain connected to chip elements 10. The remaining wire sections, defined by notches 19, will remain connected to anchoring element 60 after separation by tensile stress.

Of course, anchoring elements 60, like chip elements 10, may be such as in FIG. 5, that is, they may comprise ribs which notch the wires on forming of the chain. In this case, any additional notch-forming step is avoided.

In a situation where the chain is incorporated in a high-adherence material, especially in the case where the chain is incorporated into the object without being broken, to be broken later on by an extension of the object, the wire might break somewhere else than at the notches. To avoid this disadvantage, the wire may be coated with an anti-adhesive agent compatible with the material into which it is desired to be incorporated.

Various alterations and modifications of the present invention will occur to those skilled in the art. Although an individual incorporation of each chip element of a chain into an object has been described, the incorporation into the chain of sub-chains of chip elements, that is the breaking of the chain after a plurality of chip elements instead of after each chip element, may be envisaged. The wires are then only notched between sub-chains.

Chip elements provided with grooves for receiving the wires have been described as an example. The principles described in the present application are not limited to such a wire mounting; those skilled in the art may envisage mounting the wires in another way, such as by welding on pads provided on a surface of the chip elements.

Although the example of FIG. 3 is based on the use of microelectronic chip elements 10 connected together by two wires 12′a and 12′b, those skilled in the art may of course apply the present invention to a chain comprising several microelectronic chip elements 10 connected to a single wire 12a having notches 18a defining preferential breaking points when said wire 12a is submitted to tensile stress. The examples given hereabove can then easily be adapted by those skilled in the art, with a chip element for example comprising a single groove intended to receive the wire.

1-13. (canceled)

14. A chain comprising:
a wire,
a plurality of notches formed on the wire and configured to define preferential breaking points when the wire is submitted to tensile stress,
several microelectronic chip elements connected to the wire.

15. The chain according to claim 14, wherein
one of the microelectronic chip elements requires an antenna having a first length,
the wire is an electrically conducting wire and is connected to a first side of said one of the microelectronic chip elements for forming the antenna,
a second length of the wire between said one of the microelectronic chip elements and one of the notches is equal to the first length.

16. The chain according to claim 15, wherein two consecutives microelectronic chip elements are separated by a third length of the wire greater than the first length, and wherein an additional notch is disposed between the two consecutives microelectronic chip elements.

17. The chain according to claim 15, wherein said one of the microelectronic chip elements is provided with a groove having the wire inserted therein, the groove comprising a ridge arranged close to one end of the groove and configured to notch the wire during insertion of the wire into the groove.

18. The chain according to claim 16, wherein it comprises an anchoring element attached to the wire and disposed between two consecutive microelectronic chip elements so that the wire has a single notch between the anchoring element and each of the two consecutive microelectronic chip elements.

19. The chain according to claim 15, comprising an additional electrically conducting wire connected to a second side of said one of the microelectronic chip elements opposite to the first side, a notch is formed on the additional electrically conducting for forming an additional antenna.

20. The chain according to claim 14, wherein at least one of the notches is a cut or a partial transformation of the wire.

21. An object comprising the chain according to claim 14 incorporated in a first material, wherein the wire is coated with an anti-adhesive agent for reducing grip between the wire and the first material.

22. A method for incorporating microelectronic chip elements into an object, comprises the following steps:
introducing into the object a chain comprising several microelectronic chip elements connected to a wire having notches defining preferential breaking points when the wire is submitted to tensile stress; and
creating in the object tensile stress in an axis of the chain for breaking break the wire at one of the notches.

23. The method according to claim 22, comprising the following steps:
continuously forming the object from a stock of material; and
introducing the chain of microelectronic chip elements into the object being formed.

24. The method according to claim 23, wherein the chain of microelectronic chip elements is continuously introduced at a speed smaller than a forming speed of the object.

25. The method according to claim 24, wherein the object is formed by extrusion of a plastic material.

26. The method according to claim 23, where the chain of microelectronic chip elements is introduced step by step.
